(19) United States
(12) Patent Application Publication
(10) Pub. No.: US 2021/0020466 A1
(43) Pub. Date: Jan. 21, 2021

(54) Method for Reducing Residual Micro-Particles on Wafer Surfaces

(71) Applicant: Shanghai Huali Microelectronics Corporation, Shanghai (CN)

(72) Inventors: Yujie Nie, Shanghai (CN); Shanshan Nie, Shanghai (CN); Yangyang Qian, Shanghai (CN)

(73) Assignee: Shanghai Huali Microelectronics Corporation, Shanghai (CN)

(21) Appl. No.: 16/688,059

(22) Filed: Nov. 19, 2019

(30) Foreign Application Priority Data
Jul. 17, 2019 (CN) 201910643539.1

(51) Int. Cl. H01L 21/67; H01L 21/683; H01J 37/32

(52) U.S. Cl. CPC H01L 21/67069; H01L 21/6831; H01J 37/32715; H01J 37/32082; H01J 2237/022; H01J 2237/2007; H01J 2237/3341

(57) ABSTRACT

A method for reducing residual micro-particles on wafer surfaces includes: providing a plasma reaction etching chamber and wafer in it, a semiconductor structure is arranged on the wafer, and the first metal layer is etched; then, forming a polymer shield layer on the surface of the wafer; afterwards, implanting a plasma source into the plasma reaction etching chamber to remove charges on the surface of the wafer; finally, stopping the implantation of the plasma source, and keeping the wafer standing. According to the method, a polymer gas source is deposited to form a shield layer on the surface of the wafer in the subsequent process, a macromolecular gas source is used in the subsequent electrostatic eliminating process to eliminate static electricity, so that particles are adsorbed and carried out of the etching chamber, and particle adhesion to the wafer is avoided in the charge removal process.

### CROSS REFERENCE TO RELATED APPLICATIONS

The present application claims priority of Chinese Patent Application No. 201910643539.1 filed on Jul. 17, 2019, the disclosure of which is incorporated herein by reference in its entirety as part of the present application.

### BACKGROUND

The invention relates to the field of semiconductor manufacturing, in particular to a method for reducing residual micro-particles on wafer surfaces.

The first metal connection layer of a single damascene structure is the first layer of metal to be connected with a tungsten contact hole plug and is partially connected with a front device so as to lead out the front device. Since the dimension of nodes has reached 90 nm with the development of the integrated circuit technology, a traditional dual etching technique used for etching the first metal connection layer with a photoresist as a barrier layer has been replaced with a one-step etching technique based on a multi-layer mask of a sandwich structure, and then been replaced with a one-step etching technique using TiN or other metals as a barrier layer.

When a hard mask made from TiN or other metals is used for etching a trench of the first metal layer, etching by-products on the inner wall of a chamber may adhere to wafers in the charge removal process after the trench of the first metal layer is etched due to the material peculiarity of the metal mask. Serving as the final “gate” for transmitting external signals from integrated circuits to devices via metal wires and having the minimum characteristic dimension in the back-end-of-line process, the first metal connection layer is of great importance and has strict etching process requirements in process integration. Not only should the characteristic dimension and trench shape be strictly controlled, but also etching defects should meet the strict requirements.

During mass production, more and more polymers will be accumulated on the surface of the chamber used for etching the trench of the first metal layer with the increase of the work hours and the number of wafers. In this case, a self-cleaning process is usually adopted to remove these polymers between the wafers during the intervals between different batches of wafers. However, the self-cleaning process may severely damage components in the chamber and particularly may result in larger-density defects of electrostatic chucks; and moreover, the self-cleaning process may lead to great yield losses and cost increases. In view of this, particle sources generated with the increase of work hours should be urgently handled to guarantee the stable quality and yield of products.

Therefore, it is necessary to provide a novel method to solve the problems mentioned above.

### SUMMARY

In order to overcome the defects of the prior art, the objective of the invention is to provide a method for reducing residual micro-particles on wafer surfaces after the trench of the first metal layer is etched, so as to solve the problems of the prior art that more and more polymers will be accumulated on the surface of the chamber used for etching the trench of the first metal layer with the increase of the work hours and the number of wafers during mass production and that the self-cleaning process may severely damage the components in the chamber, result in larger-density defects, and lead to great yield losses and cost increases.

To fulfill the above objective and other related objectives, the invention provides a method for reducing residual micro-particles on wafer surfaces. The method at least includes the following steps: 1, providing a plasma reaction etching chamber and a wafer located in the plasma reaction etching chamber, wherein the wafer is provided with a semiconductor structure which is in a process condition where a trench of a first metal layer is etched; 2, forming a polymer shield layer on the surface of the wafer; 3, implanting a plasma source into the plasma reaction etching chamber to remove charges on the surface of the wafer; and 4, stopping the implantation of the plasma source, and keeping the wafer standing.

Preferably, in Step 1, the first metal layer of the semiconductor structure is etched with a barrier layer containing TiN.

Preferably, the first metal layer of the semiconductor structure is etched as follows: 1, providing a laminated structure; 2, coating the surface of the laminated structure with a photoresist; and 3, exposing, developing, and etching the laminated structure in accordance with a layout to expose the first metal layer to form a trench.

Preferably, the laminated structure sequentially comprises, from bottom to top, an inter-layer dielectric, and the first metal layer, a silicon carbide-doped film, a low-dielectric-constant silicon carbide layer, a TEOS layer, a TiN layer, a plasma-enhanced oxide, and a bottom anti-reflection coating located in the inter-layer dielectric.

Preferably, in the etching process of the first metal layer of the semiconductor structure, the laminated structure is etched as follows: first, etching the bottom anti-reflection coating, the plasma-enhanced oxide, the TiN layer, and the TEOS layer along the edge of the developed photoresist to form the trench, wherein etching is stopped at the TEOS layer; then, removing the photoresist and the bottom anti-reflection coating left on the plasma-enhanced oxide after etching; and afterwards, etching the low-dielectric-constant silicon carbide layer and the silicon carbide-doped film along the trench until the first metal layer is exposed.

Preferably, the first metal layer of the laminated structure is made from tungsten.

Preferably, an electrostatic chuck is arranged in the plasma reaction etching chamber provided in Step 1, and the wafer is located on the electrostatic chuck.

Preferably, in Step 2, the polymer shield layer is formed on the surface of the wafer as follows: depositing a heavy polymer gas source on the surface of the wafer to form the polymer shield layer.

Preferably, the heavy polymer gas source is CH4.

Preferably, in Step 3, the plasma source is implanted into the plasma reaction etching chamber to remove the charges on the surface of the wafer as follows: applying an inverse voltage to the electrostatic chuck to remove the charges on the surface of the wafer while the plasma source is implanted into the plasma reaction etching chamber.

Preferably, the plasma source implanted into the plasma reaction etching chamber in Step 3 is a macromolecular inert gas.

Preferably, the macromolecular inert gas is Ar.

Preferably, in Step 4, the implantation of the plasma source is stopped as follows: turning off a radio frequency in the plasma reaction etching chamber first, and then placing the wafer on the electrostatic chuck for standing.

Preferably, the method further includes the following steps: 5, lifting the electrostatic chuck loaded with the wafer at a stable rate; and 6, transferring the wafer out of the plasma reaction etching chamber.

Preferably, the method is applied to technical nodes with a critical dimension less than 90 nm.

From the above description, the method for removing residual micro-particles on wafer surfaces of the invention has the following beneficial effects: after the trench of the first metal layer is etched by means of the etching process, a polymer gas source is deposited to form a shield layer on the surface of the wafer in the subsequent process, and then a macromolecular gas source is used in the subsequent electrostatic eliminating process to eliminate static electricity, so that fine particles are adsorbed and carried out of the etching chamber, and particle adhesion to the wafer is avoided in the charge removal process.

### BRIEF DESCRIPTION OF THE DRAWINGS

FIG. 1 is a schematic diagram for forming a polymer shield layer on the surface of a wafer in the invention;

FIG. 2 is a structural diagram for forming a polymer shield layer on the surface of a semiconductor structure in the invention;

FIG. 3 is a schematic diagram for implanting a plasma source into a plasma reaction etching chamber to remove charges on the surface of the wafer in the invention;

FIG. 4 is a schematic diagram for standing of the wafer after a radio frequency is turned off in the invention;

FIG. 5 is a schematic diagram of particles on the surface of the wafer which is not processed through a method for reducing residual micro-particles on wafer surfaces of the invention;

FIG. 6 is a schematic diagram of the surface of the wafer which is processed through the method for reducing residual micro-particles on wafer surfaces of the invention;

FIG. 7 is a flow diagram of the method for reducing residual micro-particles on wafer surfaces of the invention;

FIG. 8 is a schematic diagram of the semiconductor structure of the invention;

FIGS. 9-11 are structural diagrams for etching a barrier layer of the semiconductor structure of the invention.

### DETAILED DESCRIPTION

The implementation of the invention is explained below with specific embodiments, and those skilled in the art can easily appreciate other advantages and effects of the invention by referring to this specification. The invention can also be implemented or applied in other forms, and from different points of views and for different applications, all details in this specification can be modified or altered in various ways without deviating from the spirit of the invention.

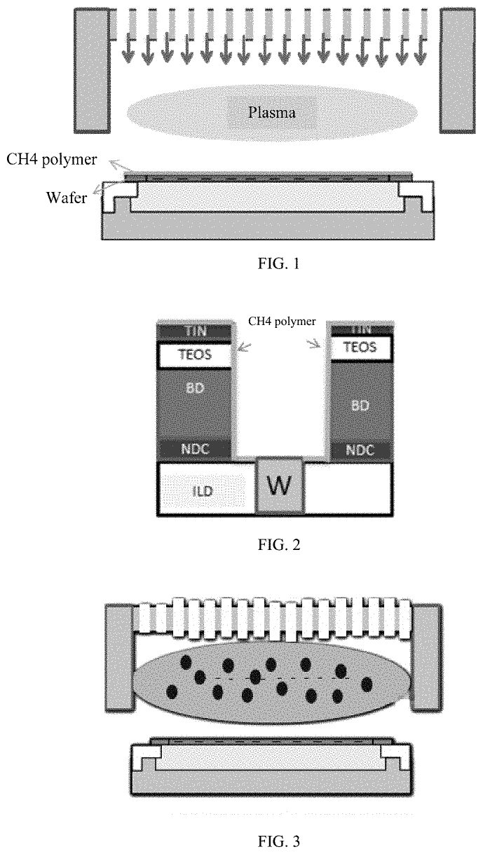

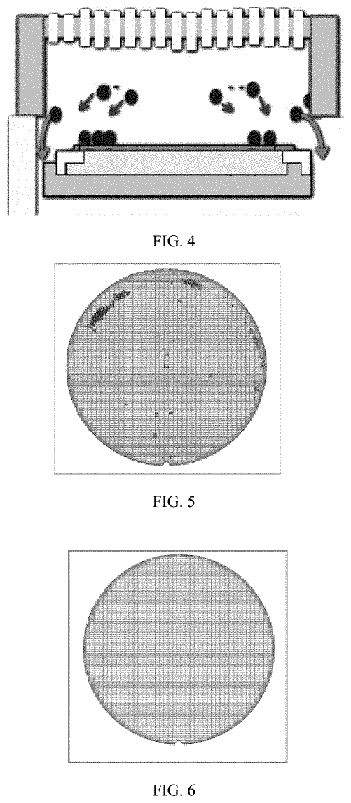

Please refer to FIG. 1-FIG. 11. What should be pointed out is that the drawings involved in the following embodiments are used for the purpose of illustratively explaining the basic conception of the invention only. Relevant components shown in the accompanying drawings are not drawn according to the actual quantity, shape, or dimension of these components in specific implementations. In actual implementations, the shape, quantity, or proportion of these components can be changed, and the configuration of these components may be more complex.

### Embodiment 1

The invention provides a method for reducing residual micro-particles on wafer surfaces.

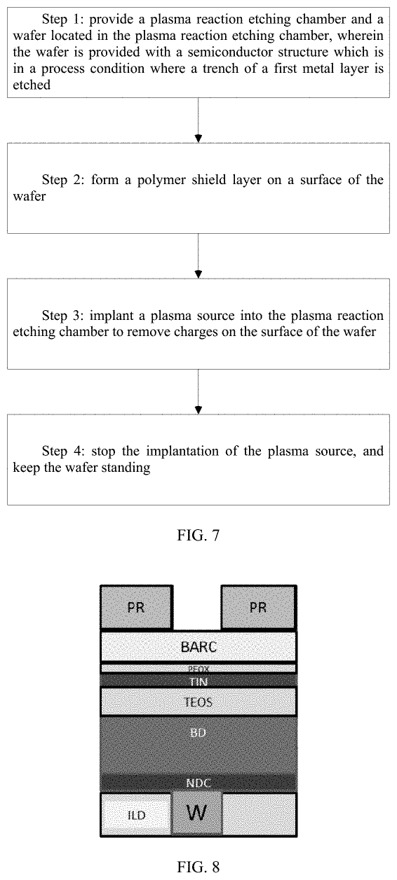

Please refer to FIG. 7 which is a flow diagram of the method for reducing residual micro-particles on wafer surfaces of the invention. The method for reducing residual micro-particles on wafer surfaces in this embodiment includes the following steps:

Step 1: a plasma reaction etching chamber and a wafer located in the plasma reaction etching chamber are provided, wherein the wafer is provided with a semiconductor structure which is in a process condition where a trench of a first metal layer is etched, that is to say, the semiconductor structure in the invention is etched with the trench of the first metal layer; and after the trench of the first metal layer is etched, the etching chamber needs to be cleaned to remove particulate pollutants generated after etching. In this embodiment, an electrostatic chuck is arranged in the plasma reaction etching chamber provided in Step 1, and the wafer is located on the electrostatic chuck. Particulate attachments will be generated after the wafer located on the electrostatic chuck is etched, and in this case, the method of the invention is used to remove the etching pollutants on the surface of the wafer so as to prevent the electrostatic chuck and the etching chamber from being polluted.

Step 2: a polymer shield layer is formed on the surface of the wafer, as shown in FIG. 1 which is a schematic diagram for forming the polymer shield layer on the surface of the wafer in the invention. In this embodiment, the polymer shield layer is formed on the surface of the wafer in Step 2 as follows: a heavy polymer gas source is deposited on the surface of the wafer to form the polymer shield layer. In this step, the heavy polymer gas source is CH4. In FIG. 1, the wafer is disposed on the electrostatic chuck, the polymer shield layer is formed by a heavy polymer gas on the surface of the wafer after the trench of the first metal layer is etched and before charges on the semiconductor structure are removed, so that plasma is protected against damage and vapor is isolated in the subsequent plasma-assisted charge removal process.

Step 3: a plasma source is implanted into the plasma reaction etching chamber to remove charges on the surface of the wafer, and in this step, the charges on the surface of the wafer are removed. In this embodiment, the plasma source is implanted into the plasma reaction etching chamber to remove the charges on the surface of the wafer in Step 3 as follows: an inverse voltage is applied to the electrostatic chuck to remove the charges on the surface of the wafer while the plasma source is implanted into the plasma reaction etching chamber. As shown in FIG. 3 which is a schematic diagram for implanting the plasma source into the plasma reaction etching chamber to remove the charges on the surface of the wafer in the invention, an inverse voltage is applied to the prime electrostatic chuck to neutralize charges on the surface of the electrostatic chuck. In this step, the plasma source implanted into the plasma reaction etching chamber is a macromolecular inert gas. Furthermore, the macromolecular inert gas in this embodiment is argon (Ar).

Step 4: the implantation of the plasma source is stopped, and the wafer is kept standing. In this embodiment, when the implantation of the plasma source is stopped in Step 4, a radio frequency in the plasma reaction etching chamber is turned off first, and then the wafer is placed on the electrostatic chuck to stand. That is to way, after the charges on the surface of the electrostatic chuck are removed, the radio frequency in the plasma reaction etching chamber is turned off first to stop the implantation of argon, and then the wafer is placed on the electrostatic chuck to stand.

The method for reducing residual micro-particles on wafer surfaces of the invention further includes the following steps:

Step 5: the electrostatic chuck loaded with the wafer is lifted at a stable rate, and after the charges on the electrostatic chuck are removed and the implantation of the plasma source is stopped for standing of the wafer, most charges on the surface of the electrostatic chuck and in the plasma reaction etching chamber are removed. In this step, the electrostatic chuck is lifted, so that the wafer can be transferred out of the plasma reaction etching chamber in the next step; and the lifting rate is kept stable, so that the electrostatic chuck is lifted at a constant speed to avoid damage to the wafer.

Step 6: the wafer is transferred out of the plasma reaction etching chamber. After the polymer shield layer is deposited on the surface of the wafer and the charges in the plasma reaction etching chamber and on the electrostatic chuck are removed, the wafer is transferred out of the etching chamber, so that residual particles on the surface of the wafer are reduced.

The method for reducing residual micro-particles on wafer surfaces is applied to technical nodes with a critical dimension less than 90 nm. Due to the material peculiarity of metal masks for the nodes with the critical dimension less than 90 nm, etching by-products on the inner wall of the chamber may adhere to wafers during the charge removal process, and the method of the invention is exactly suitable for such technical nodes.

### Embodiment 2

Please refer to FIG. 2 which is a structural diagram for forming a polymer shield layer on the surface of a semiconductor structure in the invention. In the invention, a polymer shield layer is formed on the surface of a semiconductor structure while a polymer shield layer is formed on the surface of a wafer in Step 2.

The invention provides a method for reducing residual micro-particles on wafer surfaces. Please refer to FIG. 7 which is a flow diagram of the method for reducing residual micro-particles on wafer surfaces of the invention. The method for reducing residual micro-particles on wafer surfaces in this embodiment includes the following steps:

Step 1: a plasma reaction etching chamber and a wafer located in the plasma reaction etching chamber are provided, wherein the wafer is provided with a semiconductor structure which is in a process condition where a trench of a first metal layer is etched, that is to say, the semiconductor structure is etched with the trench of the first metal layer; and after the trench of the first metal layer is etched, the etching chamber needs to be cleaned to remove particulate pollutants generated after etching. In this embodiment, an electrostatic chuck is arranged in the plasma reaction etching chamber provided in Step 1, and the wafer is located on the electrostatic chuck. Particulate attachments will be generated after the wafer located on the electrostatic chuck is etched, and in this case, the method of the invention is used to remove the etching pollutants on the surface of the wafer so as to prevent the electrostatic chuck and the etching chamber from being polluted.

In this embodiment, the first metal layer of the semiconductor structure is etched with a barrier layer containing TiN in Step 1. In this embodiment, the TiN layer serves as one barrier layer to carry out one-step independent etching on the first metal layer. Furthermore, the first metal layer of the semiconductor structure is etched as follows: 1, a laminated structure is provided; 2, the surface of the laminated structure is coated with a photoresist; and 3, the laminated structure is exposed, developed, and etched in accordance with a layout to expose the first metal layer to form the trench. That is to say, the first metal layer is provided with the laminated structure consisting of a plurality of barrier layers. When the first metal layer is etched, the laminated structure located on the first metal layer is provided first, or the laminated structure is sequentially formed layer by layer on the first metal layer from bottom to top; then, the surface of the laminated structure is coated with the photoresist, particularly, the top barrier layer of the laminated structure is coated with the photoresist; and afterwards, the photoresist is exposed and developed according to the position of the first metal layer to be etched, and then the laminated structure is etched along the side wall of a pattern formed after developing until the upper surface of the first metal layer is exposed, so that the trench is formed.

Step 2: a polymer shield layer is formed on the surface of the wafer, as shown in FIG. 1 which is a schematic diagram for forming the polymer shield layer on the surface of the wafer in the invention. In this embodiment, the polymer shield layer is formed on the surface of the wafer in Step 2 as follows: a heavy polymer gas source is deposited on the surface of the wafer to form the polymer shield layer. In this step, the heavy polymer gas source is CH4. In FIG. 1, the wafer is disposed on the electrostatic chuck, the polymer shield layer is formed by a heavy polymer gas on the surface of the wafer after the trench of the first metal layer is etched and before charges on the semiconductor structure are removed, so that plasma is protected against damage and vapor is isolated in the subsequent plasma-assisted charge removal process.

Step 3: a plasma source is implanted into the plasma reaction etching chamber to remove charges on the surface of the wafer, and in this step, the charges on the surface of the wafer are removed. In this embodiment, the plasma source is implanted into the plasma reaction etching chamber to remove the charges on the surface of the wafer in Step 3 as follows: an inverse voltage is applied to the electrostatic chuck to remove the charges on the surface of the wafer while the plasma source is implanted into the plasma reaction etching chamber. As shown in FIG. 3 which is a schematic diagram for implanting the plasma source into the plasma reaction etching chamber to remove the charges on the surface of the wafer in the invention, an inverse voltage is applied to the prime electrostatic chuck to neutralize charges on the surface of the electrostatic chuck. In this step, the plasma source implanted into the plasma reaction etching chamber is a macromolecular inert gas. Furthermore, the macromolecular inert gas in this embodiment is argon (Ar).

Step 4: the implantation of the plasma source is stopped, and the wafer is kept standing. In this embodiment, when the implantation of the plasma source is stopped in Step 4, a radio frequency in the plasma reaction etching chamber is turned off first, and then the wafer is placed on the electrostatic chuck to stand. That is to way, after the charges on the surface of the electrostatic chuck are removed, the radio frequency in the plasma reaction etching chamber is turned off first to stop the implantation of argon, and then the wafer is placed on the electrostatic chuck to stand.

The method for reducing residual micro-particles on wafer surfaces of the invention further includes the following steps:

Step 5: the electrostatic chuck loaded with the wafer is lifted at a stable rate, and after the charges on the electrostatic chuck are removed and the implantation of the plasma source is stopped for standing of the wafer, most charges on the surface of the electrostatic chuck and in the plasma reaction etching chamber are removed. In this step, the electrostatic chuck is lifted, so that the wafer can be transferred out of the plasma reaction etching chamber in the next step; and the lifting rate is kept stable, so that the electrostatic chuck is lifted at a constant speed to avoid damage to the wafer.

Step 6: the wafer is transferred out of the plasma reaction etching chamber. After the polymer shield layer is deposited on the surface of the wafer and the charges in the plasma reaction etching chamber and on the electrostatic chuck are removed, the wafer is transferred out of the etching chamber, so that residual particles on the surface of the wafer are reduced.

The method for reducing residual micro-particles on wafer surfaces is applied to technical nodes with a critical dimension less than 90 nm. Due to the material peculiarity of metal masks for the nodes with the critical dimension less than 90 nm, etching by-products on the inner wall of the chamber may adhere to wafers in the charge removal process, and the method of the invention is exactly suitable for such technical nodes.

### Embodiment 3

Please refer to FIG. 2 which is a structural diagram for forming a polymer shield layer on the surface of a semiconductor structure in the invention. In the invention, a polymer shield layer is formed on the surface of a semiconductor structure while a polymer shield layer is formed on the surface of a wafer in Step 2.

The invention provides a method for reducing residual micro-particles on wafer surfaces. Please refer to FIG. 7 which is a flow diagram of the method for reducing residual micro-particles on wafer surfaces of the invention. The method for reducing residual micro-particles on wafer surfaces in this embodiment includes the following steps:

Step 1: a plasma reaction etching chamber and a wafer located in the plasma reaction etching chamber are provided, wherein the wafer is provided with a semiconductor structure which is in a process condition where a trench of a first metal layer is etched, that is to say, the semiconductor structure in the invention is etched with the trench of the first metal layer; and after the trench of the first metal layer is etched, the etching chamber needs to be cleaned to remove particulate pollutants generated after etching. In this embodiment, an electrostatic chuck is arranged in the plasma reaction etching chamber provided in Step 1, and the wafer is located on the electrostatic chuck. Particulate attachments will be generated after the wafer located on the electrostatic chuck is etched, and in this case, the method of the invention is used to remove the etching pollutants on the surface of the wafer so as to prevent the electrostatic chuck and the etching chamber from being polluted.

In this embodiment, the first metal layer of the semiconductor structure is etched with a barrier layer containing TiN in Step 1. In this embodiment, the metal TiN layer serves as one barrier layer to carry out one-step independent etching on the first metal layer. Furthermore, the first metal layer of the semiconductor structure is etched as follows: 1, a laminated structure is provided; 2, the surface of the laminated structure is coated with a photoresist; and 3, the laminated structure is exposed, developed, and etched in accordance with a layout to expose the first metal layer to form the trench. That is to say, the first metal layer is provided with the laminated structure consisting of a plurality of barrier layers. When the first metal layer is etched, the laminated structure located on the first metal layer is provided first, or the laminated structure is sequentially formed layer by layer on the first metal layer from bottom to top; and then, the surface of the laminated structure is coated with the photoresist, particularly, the top barrier layer of the laminated structure is coated with the photoresist; and afterwards, the photoresist is exposed and developed according to the position of the first metal layer to be etched, and then the laminated structure is etched along the side wall of a pattern formed after developing until the upper surface of the first metal layer is exposed, so that the trench is formed.

Furthermore, as shown in FIG. 8 which is a schematic diagram of the semiconductor structure of the invention, the laminated structure sequentially comprises, from bottom to top, an inter-layer dielectric (ILD), and a first metal layer (W), a silicon carbide-doped film (NDC), a low-dielectric-constant silicon carbide layer (BD), a TEOS layer, a TiN layer, a plasma-enhanced oxide (PEOX), and a bottom anti-reflection coating (BARC) located in the inter-layer dielectric. The first metal layer of the laminated structure is made from tungsten (W).

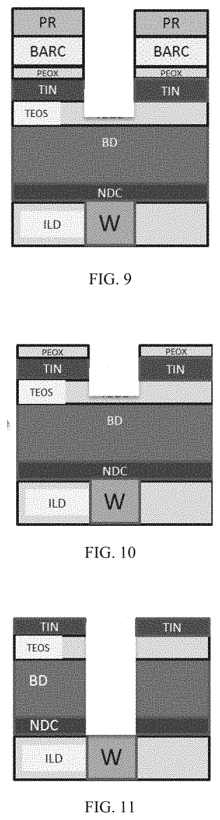

FIGS. 9-11 are structural diagrams for etching a barrier layer of the semiconductor structure in this embodiment of the invention. In the etching process of the first metal layer of the semiconductor structure, a hard mask on the first metal layer is etched, as shown in FIG. 9; the laminated structure is etched as follows: the bottom anti-reflection coating (BARC), the plasma-enhanced oxide (PEOX), the TiN layer and the TEOS layer are etched along the edge of the developed photoresist to form the trench, wherein etching is stopped at the TEOS layer; then, the photoresist and the bottom anti-reflection coating (BARC) left on the plasma-enhanced oxide (PEOX) are removed (referring to FIG. 10 which is a schematic diagram for removing the photoresist after the hard mask is etched); afterwards, the low-dielectric-constant silicon carbide layer (BD) and the silicon carbide-doped film (NDC) are etched along the trench until the first metal layer (W) is exposed (referring to FIG. 11 which is a schematic diagram for exposing the first metal layer).

When TiN is used as the hard mask to etch the trench of the first metal layer, etching by-products on the inner wall of the chamber may adhere to the wafer in the charge removal process when the trench of the first metal layer is etched due to the material peculiarity of the metal mask; and the first metal connection layer having the minimum characteristic dimension in the back-end-of-line process has strict etching process requirements in process integration.

Step 2: a polymer shield layer is formed on the surface of the wafer, as shown in FIG. 1 which is a schematic diagram for forming the polymer shield layer on the surface of the wafer in the invention. In this embodiment, the polymer shield layer is formed on the surface of the wafer in Step 2 as follows: a heavy polymer gas source is deposited on the surface of the wafer to form the polymer shield layer. In this step, the heavy polymer gas source is CH4. In FIG. 1, the wafer is disposed on the electrostatic chuck, the polymer shield layer is formed by a heavy polymer gas on the surface of the wafer after the trench of the first metal layer is etched and before charges on the semiconductor structure are removed, so that plasma is protected against damage and vapor is isolated in the subsequent plasma-assisted charge removal process.

Step 3: a plasma source is implanted into the plasma reaction etching chamber to remove charges on the surface of the wafer, and in this step, the charges on the surface of the wafer are removed. In this embodiment, the plasma source is implanted into the plasma reaction etching chamber to remove the charges on the surface of the wafer in Step 3 as follows: an inverse voltage is applied to the electrostatic chuck to remove the charges on the surface of the wafer while the plasma source is implanted into the plasma reaction etching chamber. As shown in FIG. 3 which is a schematic diagram for implanting the plasma source into the plasma reaction etching chamber to remove the charges on the surface of the wafer in the invention, an inverse voltage is applied to the prime electrostatic chuck to neutralize charges on the surface of the electrostatic chuck. In this step, the plasma source implanted into the plasma reaction etching chamber is a macromolecular inert gas. Furthermore, the macromolecular inert gas in this embodiment is argon (Ar).

Step 4: the implantation of the plasma source is stopped, and the wafer is kept standing. In this embodiment, when the implantation of the plasma source is stopped in Step 4, a radio frequency in the plasma reaction etching chamber is turned off first, and then the wafer is placed on the electrostatic chuck to stand. That is to way, after the charges on the surface of the electrostatic chuck are removed, the radio frequency in the plasma reaction etching chamber is turned off first to stop the implantation of argon, and then the wafer is placed on the electrostatic chuck to stand.

The method for reducing residual micro-particles on wafer surfaces of the invention further includes the following steps:

Step 5: the electrostatic chuck loaded with the wafer is lifted at a stable rate, and after the charges on the electrostatic chuck are removed and the implantation of the plasma source is stopped for standing of the wafer, most charges on the surface of the electrostatic chuck and in the plasma reaction etching chamber are removed. In this step, the electrostatic chuck is lifted, so that the wafer can be transferred out of the plasma reaction etching chamber in the next step; and the lifting rate of is kept stable, so that the electrostatic chuck is lifted at a constant speed to avoid damage to the wafer.

Step 6: the wafer is transferred out of the plasma reaction etching chamber. After the polymer shield layer is deposited on the surface of the wafer and the charges in the plasma reaction etching chamber and on the electrostatic chuck are removed, the wafer is transferred out of the etching chamber, so that residual particles on the surface of the wafer are reduced.

The method for reducing residual micro-particles on wafer surfaces is applied to technical nodes with a critical dimension less than 90 nm. Due to the material peculiarity of metal masks for the nodes with the critical dimension less than 90 nm, etching by-products on the inner wall of the chamber may adhere to wafers in the charge removal process, and the method of the invention is exactly suitable for such technical nodes.

According to the method for reducing residual micro-particles on wafer surfaces of the invention, after the trench of the first metal layer is etched by means of the etching process, a polymer gas source is deposited to form a shield layer on the surface of the wafer in the subsequent process, and then a macromolecular gas source is used in the subsequent electrostatic eliminating process to eliminate static electricity, so that fine particles are adsorbed and carried out of the etching chamber, and particle adhesion to the wafer is avoided in the charge removal process.

The above embodiments are only used for illustratively explaining the principle and effects of the invention, and are not intended to limit the invention. Any person skilled in the art can modify or transform the above embodiments without deviating from the spirit and going beyond the scope of the invention. Therefore, all equivalent modifications or transformations achieved by those ordinarily in the art without deviating from the spirit and technical idea of the invention should also fall within the scope defined by the claims of the invention.

What is claimed is:

1. A method for reducing residual micro-particles on wafer surfaces, at least including the following steps:
Step 1: providing a plasma reaction etching chamber and a wafer located in the plasma reaction etching chamber, wherein the wafer is provided with a semiconductor structure which is in a process condition where a trench of a first metal layer is etched;
Step 2: forming a polymer shield layer on a surface of the wafer;
Step 3: implanting a plasma source into the plasma reaction etching chamber to remove charges on the surface of the wafer; and
Step 4: stopping the implantation of the plasma source, and keeping the wafer standing.

2. The method for reducing residual micro-particles on wafer surfaces according to claim 1, wherein the first metal layer of the semiconductor structure is etched in Step 1 with a barrier layer containing TiN.

3. The method for reducing residual micro-particles on wafer surfaces according to claim 2, wherein the first metal layer of the semiconductor structure is etched as follows: 1, providing a laminated structure; 2, coating a surface of the laminated structure with a photoresist; and 3, exposing, developing, and etching the laminated structure in accordance with a layout to expose the first metal layer to form the trench.

4. The method for reducing residual micro-particles on wafer surfaces according to claim 3, wherein the laminated structure sequentially comprises, from bottom to top, an inter-layer dielectric, and a first metal layer, a silicon carbide-doped film, a low-dielectric-constant silicon carbide layer, a TEOS layer, a TiN layer, a plasma-enhanced oxide and a bottom anti-reflection coating located in the inter-layer dielectric.

5. The method for reducing residual micro-particles on wafer surfaces according to claim 4, wherein in the etching process of the first metal layer of the semiconductor structure, the laminated structure is etched as follows: first, etching the bottom anti-reflection coating, the plasma-enhanced oxide, the TiN layer and the TEOS layer along an edge of the developed photoresist to form the trench, wherein etching is stopped at the TEOS layer; then, removing the photoresist and the bottom anti-reflection coating left on the plasma-enhanced oxide after etching; and afterwards, etching the low-dielectric-constant silicon carbide layer and the silicon carbide-doped film along the trench until the first metal layer is exposed.

6. The method for reducing residual micro-particles on wafer surfaces according to claim 5, wherein the first metal layer of the laminated structure is made from tungsten.

7. The method for reducing residual micro-particles on wafer surfaces according to claim 1, wherein an electrostatic chuck is arranged in the plasma reaction etching chamber provided in Step 1, and the wafer is located on the electrostatic chuck.

8. The method for reducing residual micro-particles on wafer surfaces according to claim 1, wherein the polymer shield layer is formed on the surface of the wafer in Step 2 as follows:
depositing a heavy polymer gas source on the surface of the wafer to form the polymer shield layer.

9. The method for reducing residual micro-particles on wafer surfaces according to claim 8, wherein the heavy polymer gas source is CH4.

10. The method for reducing residual micro-particles on wafer surfaces according to claim 7, wherein in Step 3, the plasma source is implanted into the plasma reaction etching chamber to remove the charges on the surface of the wafer as follows: applying an inverse voltage to the electrostatic chuck to remove the charges on the surface of the wafer while the plasma source is implanted into the plasma reaction etching chamber.

11. The method for reducing residual micro-particles on wafer surfaces according to claim 1, wherein the plasma source implanted into the plasma reaction etching chamber in Step 3 is a macromolecular inert gas.

12. The method for reducing residual micro-particles on wafer surfaces according to claim 10, wherein the plasma source implanted into the plasma reaction etching chamber in Step 3 is a macromolecular inert gas.

13. The method for reducing residual micro-particles on wafer surfaces according to claim 11, wherein the macromolecular inert gas is Ar.

14. The method for reducing residual micro-particles on wafer surfaces according to claim 7, wherein in Step 4, the implantation of the plasma source is stopped as follows: turning off a radio frequency in the plasma reaction etching chamber first, and then placing the wafer on the electrostatic chuck for standing.

15. The method for reducing residual micro-particles on wafer surfaces according to claim 9, wherein in Step 4, the implantation of the plasma source is stopped as follows: turning off a radio frequency in the plasma reaction etching chamber first, and then placing the wafer on the electrostatic chuck for standing.

16. The method for reducing residual micro-particles on wafer surfaces according to claim 1, wherein the method further includes: Step 5, lifting the electrostatic chuck loaded with the wafer at a stable rate; and Step 6, transferring the wafer out of the plasma reaction etching chamber.

17. The method for reducing residual micro-particles on wafer surfaces according to claim 1, wherein the method is applied to technical nodes with a critical dimension less than 90 nm.
